(19) United States
(12) Patent Application Publication
(10) Pub. No.: US 2013/0045362 A1
(43) Pub. Date: Feb. 21, 2013

(54) METHOD FOR MAKING A CONDUCTIVE LAMINATE

(71) Applicants: Chien-Cheng Chang, Taipei City (TW); Yu-Chun Chien, Taipei City (TW); Da-Shan Lin, Taipei City (TW); Han-Hsiang Lin, Taipei City (TW)

(72) Inventors: Chien-Cheng Chang, Taipei City (TW); Yu-Chun Chien, Taipei City (TW); Da-Shan Lin, Taipei City (TW); Han-Hsiang Lin, Taipei City (TW)

(73) Assignee: FAR EASTERN NEW CENTURY CORPORATION, Taipei City (TW)

(21) Appl. No.: 13/592,254

(22) Filed: Aug. 22, 2012

(30) Foreign Application Priority Data
Nov. 5, 2010 (TW) 099138132
Oct. 27, 2011 (TW) 100139124

(51) Int. Cl. G03F 7/20; H01B 1/02

(52) U.S. Cl. 428/141; 430/325; 430/296

(57) ABSTRACT

A method for making a conductive laminate includes: (a) forming a photocurable layer on a substrate, the photocurable layer including at least one photocurable prepolymer that has a plurality of reactive functional groups and that has a functional group equivalent weight ranging from 70 to 700 g/mol; (b) covering partially the photocurable layer using a patterned mask; (c) exposing the photocurable layer through the patterned mask using a first light source; (d) removing the patterned mask; (e) exposing the photocurable layer to a second light source to cure second regions of the photocurable layer which have not been cured, so as to form a microstructure; and (f) forming a conductive layer on the microstructure.

### CROSS-REFERENCE TO RELATED APPLICATION

This application claims priority of Taiwanese application no.100139124, filed on Oct. 27, 2011, and is a continuation-in-part (CIP) of co-pending U.S. patent application Ser. No. 13/231863, filed on Sep. 13, 2011.

### BACKGROUND OF THE INVENTION

1. Field of the Invention

This invention relates to a method for making a conductive laminate, more particularly to a method for making a conductive laminate with a microstructure.

2. Description of the Related Art

A conductive laminate can be applied to an optoelectronic device, such as a display, a touch panel, a sensor, an electronic paper, an optical element, etc.

In the following, a typical conductive laminate, which can serve as electrode plates in a resistive touch panel or a capacitive touch panel, is exemplified. Such conductive laminate is a substrate coated with a transparent conductive layer that is made of metal or metal oxide. When a touch surface of the touch panel is pressed by a stylus pen or a finger to input information, a part of an upper conductive laminate, which is subjected to the pressing force, is deformed to contact a lower conductive laminate, such that the transparent conductive layers of the two spaced apart upper and lower conductive laminates are electrically connected at a position corresponding to the pressed position on the touch surface to input a signal. When the touch surface is released from the pressing, the upper conductive laminate moves upward to an original position.

However, when the upper and lower conductive laminates are in contact with each other, a sticking may occur to obstruct the upward movement of the upper conductive laminate. Accordingly, once the upper conductive laminates moves back to the original position, the transparent conductive film of the lower conductive laminate is subjected to an upward drawing force. With the repeat of pressing operation, the transparent conductive layer maybe damaged or delaminated from the substrate, thereby causing an increase in a resistance value of the transparent conductive layer. In this case, the touch panel may not be normally operated. Therefore, it is required to improve a bonding strength between the substrate and the transparent conductive layer, and to improve structural strength of the conductive laminate.

US patent application publication no. 2003/0087119 discloses a transparent conductive laminate including a transparent polymeric substrate, a transparent conductive layer formed on the transparent polymeric substrate, and a covering layer formed on the transparent conductive layer. The covering layer may be made of a material selected from metal oxide, metal nitride, metal nitrogen oxide, carbon, nitrogen carbide, silicon carbide, etc. By virtue of the covering layer, damage and delamination of the transparent conductive layer due to repeated pressing and sliding operations of the touch panel maybe prevented. However, the method for forming the transparent conductive laminate involves a sputtering step for forming the covering layer that is performed after another sputtering step for forming the transparent conductive laminate, and thus is relatively complex.

U.S. Pat. No. 6,629,833 discloses a transparent conductive laminate having a transparent plastic substrate, a transparent conductive layer, and a resin layer that contains an ionic group and that is sandwiched between the transparent plastic substrate and the transparent conductive layer. By virtue of the resin layer that contains the ionic group and that is adhesive, the transparent conductive layer can be adhered securely to the transparent plastic substrate, thus preventing the transparent conductive laminate from being damaged or delaminated due to the repeated pressing and sliding operations of the touch panel. However, because the resin layer is adhesive, some tiny particles such as dust may adhere to the transparent conductive layer during the process for forming the transparent conductive laminate.

In addition to the above mentioned techniques, the transparent conductive layer of the conductive laminate is also proposed to be formed into a microstructure. By virtue of the microstructure, a contact area between the upper and lower conductive laminates can be reduced, thereby alleviating the sticking between the upper and lower conductive laminates, and thereby preventing the transparent conductive layer from being damaged or delaminated due to the repeated pressing operations of the touch panel.

Typically, the microstructure may be formed by a heat-embossing method, a photolithography method, etc. However, these methods have the following drawbacks.

For example, when using the heat-embossing method, since the embossing force for forming the microstructure is hard to be evenly applied to the transparent conductive film, the microstructure formed thereby may have poor pattern uniformity and precision. Moreover, the microstructure formed by this method may have angulated portions such as a serrated portion, a right-angled portion, or a trapezoidal portion. Since the angulated portions are stress concentration regions, the existence of such microstructure may accelerate the delamination of the transparent conductive film.

When using the photolithography method as disclosed in U.S. Pat. No. 6,036,579, an etchant for forming the microstructure is relatively expensive, and may cause environmental pollution. Moreover, the microstructure formed by this method may also have the angulated portions similar to the microstructure formed by the heat-embossing method.

### SUMMARY OF THE INVENTION

Therefore, an object of the present invention is to provide a method for making a conductive laminate that can overcome the aforesaid drawbacks associated with the prior art.

Accordingly, a method for making a conductive laminate of this invention comprises:
(a) forming a photocurable layer on a substrate, the photocurable layer including a photocurable composition having at least one photocurable prepolymer that has a plurality of reactive functional groups and that has a functional group equivalent weight ranging from 70 to 700 g/mol;
(b) covering partially the pho to curable layer using a patterned mask;
(c) exposing the photocurable layer using a first light source so that the photocurable layer is cured at first regions which are exposed through the patterned mask;
(d) removing the patterned mask;
(e) exposing the photocurable layer using a second light source to cure second regions of the photocurable layer which have not been cured, such that the first and second regions having different surface heights, thereby forming a microstructure on the substrate; and
(f) forming a conductive layer on the microstructure.

### BRIEF DESCRIPTION OF THE DRAWINGS

Other features and advantages of the present invention will become apparent in the following detailed description of the preferred embodiments of the invention, with reference to the accompanying drawings, in which:

FIGS. 1 to 6 are schematic side views illustrating consecutive steps of a method for forming a conductive laminate according to the preferred embodiment of the present invention.

### DETAILED DESCRIPTION OF THE PREFERRED EMBODIMENTS

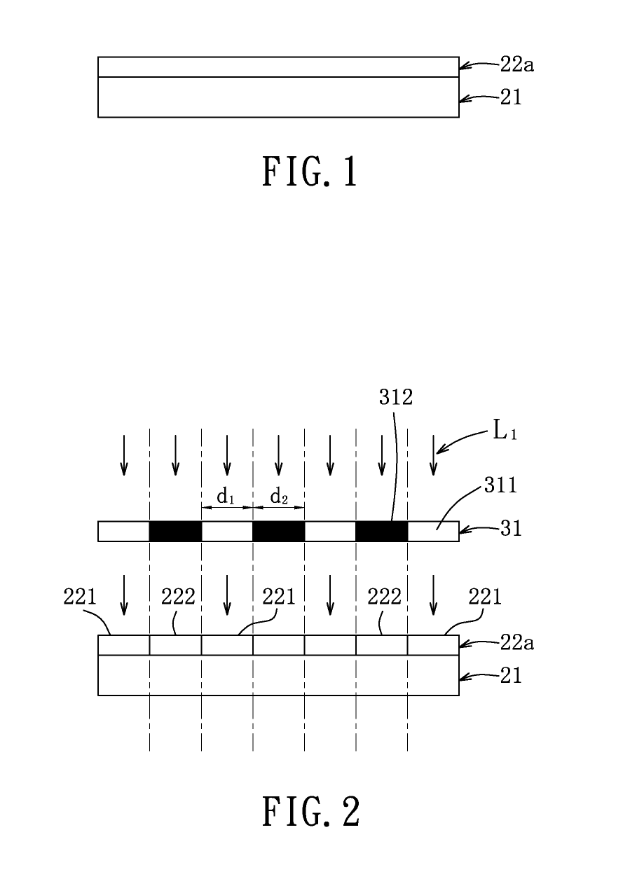

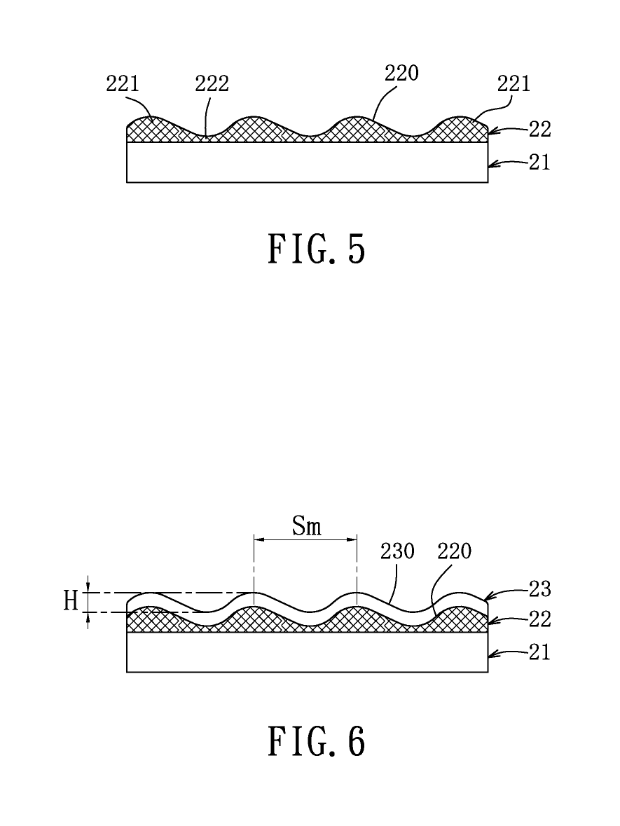

Referring to FIGS. 1 to 6, the preferred embodiment of a method for making a conductive laminate of this invention comprises the following steps (a) to (f) in sequence.

In step (a), a substrate 21 is coated with a paste (not shown) to form a paste layer. The paste includes a solvent, a photocurable composition that has at least one photocurable prepolymer, and a photoinitiator. The photocurable prepolymer has a plurality of reactive functional groups capable of taking part in a cross-linking reaction in the presence of free radicals, and a functional group equivalent weight ranging from 70 to 700 g/mol. Then, the paste layer is dried (for example by heating) to remove the solvent from the paste layer and to form a photocurable layer 22a that is uncured on the substrate 21 (see FIG. 1).

In step (b), the photocurable layer 22a is partially covered using a patterned mask 31.

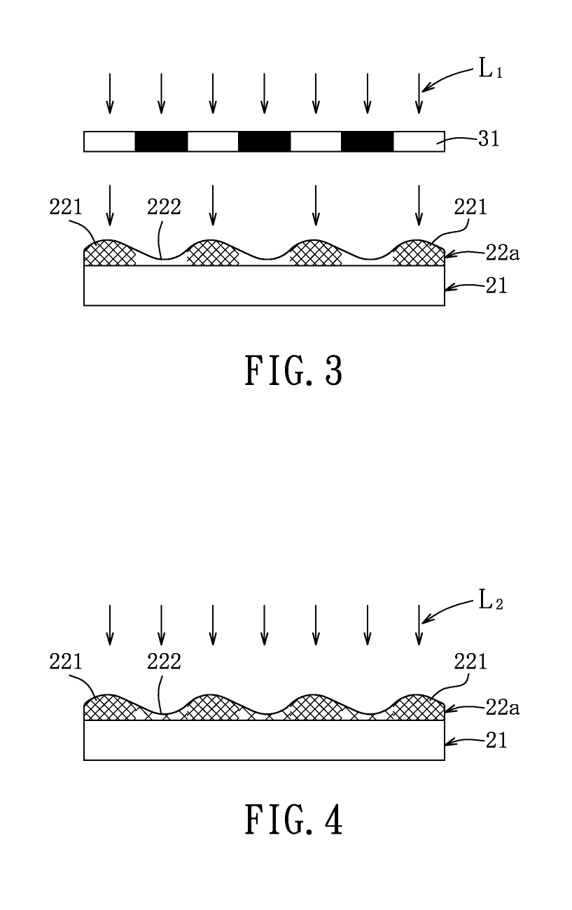

In step (c), the photocurable layer 22a is exposed using a first light source L1 so that the photocurable prepolymer in the photocurable layer 22a is cured (i.e., cross-linked) at first regions 221 which are exposed through the patterned mask 31 (see FIGS. 2 and 3).

In step (d), the patterned mask 31 is removed.

In step (e), the photocurable layer 22a that is partially cured is exposed using a second light source L2 to cure second regions 222 of the photocurable layer 22a which have not been cured in step (c), such that the first and second regions 221, 222 of the photocurable layer 22a having different surface heights so as to provide a surface roughness (Rz), thereby forming a microstructure 22 on the substrate 21 (see FIG. 4).

In step (f), a transparent conductive layer 23 is formed on the microstructure 22 (see FIG. 6).

The patterned mask 31 has one or more light-transmissive regions 311 for passage of light from the first light source L1, and one or more light impermeable regions 312 for blocking, absorbing, or reflecting light from the first light source L1. The width (d₁) of each of the light-transmissive regions 311 ranges from 50 μm to 250 μm, and the width (d₂) of each of the light impermeable regions 312 ranges from 50 μm to 250 μm. Thus, the width of each of the first regions 221 also ranges from 50 μm to 250 μm.

The reactive functional groups of the photocurable prepolymer should not be limited so long as they are photocurable. Non-limiting examples of the reactive functional group include an alkenyl group. When the alkenyl groups are included, non-limiting examples of the photocurable prepolymer include an acrylic-based compound, an ether-based compound including a vinyl group, a styrene-based compound, a thiolene-based compound, etc.

The photocurable prepolymer may also be a monomer, an oligomer, or a combination thereof.

The functional group equivalent weight of the photocurable prepolymer ranges preferably from 70 to 700 g/mol, more preferably from 80 to 600 g/mol, and most preferably from 85 to 400 g/mol. In this application, the functional group equivalent weight of the photocurable prepolymer is defined by the molecular weight of the photocurable prepolymer divided by the number of the reactive functional groups.

In the following, the microstructure forming mechanism is described.

The photocurable layer 22a is formed by coating the substrate 21 with the paste that includes the solvent, the photocurable composition having at least one of the aforesaid photocurable prepolymers, and the photoinitiator. When the first regions 221 of the photocurable layer 22a are exposed to the first light source L1 through the patterned mask 31, the photoinitiator generates free radicals. The free radicals initiate the cross-linking reaction of the photocurable prepolymer at the first regions 221 of the photocurable layer 22a.

With the progressing of the cross-linking reaction in the first regions 221 of the uncured photocurable layer 22a, the average molecular weight of the molecules and the viscosity increases in the first regions 221, and the concentration of unreacted photocurable composition is also gradually reduced. In this case, the unreacted photocurable composition in the second regions 222 of the photocurable layer 22a has a relatively high concentration. Since a material tends to diffuse from the zone of high concentration toward that of low concentration, the unreacted photocurable composition in the second regions 222 flows toward the first regions 221. The cross-linking reaction is terminated when the viscosity reaches a limit value. Accordingly, as shown in FIG. 3, after the step (c), the cured portion of the photocurable layer 22a protrudes in the first regions 221, and the non-cured portion of the photocurable layer 22a is indented in the second regions 222, thereby forming the microstructure 22. The smaller the molecular weight of the photocurable composition, the faster the unreacted photocurable composition in the second regions 222 flows toward the first regions 221. In the case of using the photocurable composition with a smaller molecular weight, an average difference value between the surface heights of the first and second regions 221, 222 (i.e., a surface roughness (Rz) of the microstructure 22) becomes larger.

Similarly, the larger the number of the reactive functional groups of the photocurable composition, the more active will be the curing of the photocurable layer 22a. In the case of using the photocurable composition with larger functional group equivalent weight, the unreacted photocurable composition in the second regions 222 flows toward the first regions 221 faster, and the average difference value between the surface heights of the first and second regions 221, 222 (i.e., the surface roughness (Rz) of the microstructure 22) becomes larger.

It should be noted that, instep (c), the first regions 221 may be fully cured or partially cured. As long as the photocurable composition at the first regions 221 is no longer flowable, the curing degree of first regions 221 of the photocurable layer 22a should not be limited.

The solvent used in step (a) may be any one that can sufficiently dissolve the photo curable composition and the photoinitiator, and may be selected from alcohols, ketones, esters, halogenated solvents, hydrocarbons, etc. Examples of the solvent include acetone, acetonitrile, chloroform, chlorophenol, cyclohexane, cyclohexanone, cyclopentanone, dichloromethane, diethyl acetate, dimethyl carbonate, ethanol, ethyl acetate, N,N-dimethyl acetamide, 1,2-propanediol, 2-hexanone, methanol, methyl acetate, butyl acetate, toluene, tetrahydrofuran, and combinations thereof.

The photoinitiator used in the paste can be any one that may facilitate photocurability of the photocurable composition, and may be selected from the group consisting of vinyl phenone derivatives, benzophenone derivatives, Michler's ketone, benzyne, benzyl derivatives, benzoin derivatives, benzoin methyl ether derivatives, α-acyloxy ester, thioxanthone derivatives, anthraquinone derivatives, and combinations thereof. The amount of the photoinitiator used in the paste is not limited, and is preferably not less than 0.01 wt % based on a total weight of the paste.

Preferably, the paste has a solid content ranging from 10 wt % to 80 wt %. When the solid content is less than 10 wt %, the microstructure 22 would not be formed even when the photocurable layer 22a is exposed to the first light source L1 (such as UV light). When the solid content is more than 80 wt %, it is difficult to coat the paste onto the substrate 21, and the paste tends to crack after being cured. Therefore, the solid content of the paste ranges preferably from 15 wt % to 60 wt %, and more preferably from 20 wt % to 40 wt %.

The transparent conductive layer 23 is made of metal or metallic compound. The metal is selected from the group consisting of gold, silver, platinum, lead, copper, aluminum, nickel, chromium, titanium, iron, cobalt, tin, and combinations thereof. The metallic compound is selected from the group consisting of indium oxide, tin oxide, titanium oxide, aluminum oxide, zinc oxide, gallium oxide, indium tin oxide, and combinations thereof. Preferably, the transparent conductive layer 23 is made of indium tin oxide.

The transparent conductive layer 23 can be made by any process such as dry or wet process as long as the process for forming the transparent conductive layer 23 would not damage the microstructure 22. The dry process maybe a PVD (physical vapor deposition) process or a CVD (chemical vapor deposition) process. The PVD process can be selected from, but is not limited to, a sputtering deposition process (such as DC magnetron sputtering, RF magnetron sputtering, etc.), a vacuum evaporation process (such as pulsed laser evaporation, E-beam evaporation, etc.), and an ion plating process. The wet process may be, but is not limited to, a spraying process or a screen printing process. Preferably, the transparent conductive layer 23 is made using the sputtering deposition process.

Preferably, the substrate 21 is made of transparent insulating material such as polymer. The polymer is selected from the group consisting of polyester-based resin, polyether-based resin, polycarbonate-based resin, polyamide-based resin, polyimide-based resin, polyolefin-based resin, acrylic-based resin, polyvinyl chloride-based resin, polystyrene-based resin, polyvinyl alcohol-based resin, polyarylate-based resin, polyphenylene sulfide-based resin, polyvinylidene chloride-based resin, methylacrylic-based resin, acetyl cellulose-based resin, diacetyl cellulose-based resin, triacetyl cellulose-based resin and combinations thereof. More preferably, the substrate 21 is made of polyethylene terephthalate.

Preferably, the thickness of the substrate 21 ranges from 2 μm to 300 μm, and more preferably from 10 μm to 130 μm. If the thickness of the substrate 21 is less than 2 μm, the mechanical strength of the substrate 21 may be insufficient, so that the transparent conductive layer 23 may not be formed continuously. If the thickness of the substrate 21 is more than 300 μm, the substrate 21 may become inflexible, so that the bending workability of the transparent conductive layer 23 may be adversely affected.

Preferably, the first light source L1 is UV light, visible light, an electron beam, or an X-ray, and the UV light is more preferable. The exposure dose of the first light source L1 is not limited. In general, the higher the exposure dose, the better will be the formation of the microstructure 22. However, the high exposure dose results in relatively high energy consumption and cost. If the exposure dose is too low, the curing time for the photocurable composition is relatively long. In consideration of the cost and the curing time, the exposure dose of the first light source L1 is preferably not less than 70 mJ/cm², and more preferably ranges from 70 mJ/cm² to 4000 mJ/cm². If the exposure dose is less than 70 mJ/cm², the microstructure 22 may not be formed. If the exposure dose is more than 4000 mJ/cm², the substrate 21 maybe deformed. Therefore, the exposure dose of the first light source L1 is more preferably from 100 mJ/cm² to 3500 mJ/cm², and most preferably from 400 mJ/cm² to 1500 mJ/cm².

Preferably, the second light source L2 may also be UV light, visible light, electron beam, or X-ray, and the UV light is more preferable. The exposure dose of the second light source L2 is not limited as long as the photocurable layer 22a (especially the second regions 222) can be fully cured. Besides, the first and second light sources L1, L2 may be the same or different.

FIG. 6 is a schematic side view illustrating the conductive laminate made by the method of the preferred embodiment of this invention. The conductive laminate includes the substrate 21, the microstructure 22 that is formed on the substrate 21, and the transparent conductive layer 23 that is formed on an upper surface 220 of the microstructure 22. Since the transparent conductive layer 23 is formed along a surface topography of the upper surface 220 of the microstructure 22, an upper surface 230 of the transparent conductive layer 23 has a substantially the same surface configuration as the upper surface 220 of the microstructure 22. That is to say, the transparent conductive layer 23 has a plurality of protruded and indented regions in positions corresponding to the first and second regions 221, 222 of the microstructure 22, respectively. Besides, based on practical requirements, the surface roughness of the transparent conductive layer 23 can be adjusted by the functional group equivalent weight of the photocurable composition and by the exposure dose of the first light source L1. Preferably, the upper surface 230 of the transparent conductive layer 23 has a Rz value ranging from 0.5 μm to 3.5 μm, and a Sm value of the upper surface 230 of the transparent conductive layer 23 ranging from 0.05 mm to 0.35 mm.

The Rz value of the surface roughness is determined by a ten-point average value of surface height differences (H) (see FIG. 6) among two adjacent protruded and intended regions, and the Sm value of the surface roughness is determined by an average value of mean spacings (see FIG. 6) among two peak parts of two adjacent protruded regions. In this embodiment, the Rz value and the Sm value are measured using a probing surface roughness meter (available from KOSAKA Laboratory Ltd., Japan, Model No. ET4000A).

Preferably, the thickness of the transparent conductive layer 23 ranges from 10 nm to 300 nm, and more preferably, from 10 nm to 200 nm. If the thickness is less than 10 nm, the transparent conductive layer 23 may not be formed as a continuous film with good electrical conductivity (for example, surface resistivity less than 10³ Ω/square). If the thickness of the transparent conductive layer 23 is too large, the transparency of the transparent conductive layer 23 may be reduced.

The conductive laminate obtained by the method according to the present invention has the protruded and indented regions thereon. As such, when the conductive laminate according to the present invention is used as one of two electrode plates of a touch panel, a contact area between the two electrode plates is relatively small compared to the touch panel including two electrode plates each having a flat transparent conductive layer. Therefore, if the touch panel having the conductive laminate of this invention serves as at least one of the two electrode plates, the sticking between the two electrode plates can be alleviated, thereby preventing the transparent conductive layer 23 from being damaged and delaminated.

Besides, the upper surface 230 of the transparent conductive layer 23 has a wave-shaped cross-section profile. Compared to the conventional conductive laminate with the angulated portions, the conductive laminate according to the present invention is less likely to cause a stress concentration in response to a pressing operation of the touch panel. Hence, an undesirable increase in electrical resistance of the transparent conductive layer 23 due to the stress concentration can be avoided.

Based on these advantages, the conductive laminate according to the present invention is applicable to a touch panel or a display, and is suitable to serve as an electrode plate of the touch panel.

The present invention will now be explained in more detail below by way of the following examples. It should be noted that the examples are only for illustration and not for limiting the scope of the present invention.

### Example 1

### Formation of a Conductive Laminate

0.2 g of a photocurable prepolymer having reactive functional groups and a functional group equivalent weight of 99.3 g/mol (available from Sartomer, trade name: SR444) was mixed with 0.8 g of toluene and 0.02 g of a photo initiator (available from Ciba, trade name: 1-184) to obtain a paste (1.02 g) having a solid content of 20 wt %.

The paste was dropped on a polyester-based substrate (available from Toyobo Co., Ltd., trade name: A4300, 5 cm×5 cm×100 μm), and the paste was evenly distributed on the substrate using spin coating at a speed of 1000 rpm for 40 seconds. Then, the substrate coated with the paste was disposed in an oven maintained at 80° C. for 3 minutes to remove the solvent (i.e., toluene), and subsequently moved to another oven maintained at 100° C. to be subjected to a heat treatment for 2 minutes, followed by cooling to room temperature to form the photocurable layer on the substrate.

A patterned mask having a line spacing of 50 μm and a line width of 50 μm was disposed on the photocurable layer. The photocurable layer was exposed to a first UV light source (the first light source L1) of an UV exposure machine (available from US Fusion) at an exposure dose of 520 mJ/cm² in a nitrogen atmosphere. Thereafter, exposed first regions of the photocurable layer were formed into cured protruded regions, and unexposed second regions were formed into uncured indented regions. After the patterned mask was removed, the photocurable layer was further exposed to a second UV light source (the second light source L2) at an exposure dose of 450 mJ/cm² in a nitrogen atmosphere. All of the first and second regions were cured to have different surface heights and to obtain the microstructure.

The substrate with the microstructure was subjected to a sputtering procedure in a magnetron sputtering chamber. A sputtering target material is indium tin oxide (ITO) (Sn/(In+Sn)=10 wt %). After the vacuum degree in the magnetron sputtering chamber reached 3×10⁻⁶ Torr, sputtering gases including Ar and O₂ gases (O₂/Ar=0.02) were introduced into the magnetron sputtering chamber so that a working pressure inside the chamber reached 5×10⁻⁴ Torr. The sputtering power of 4 KW was used, and the substrate was at room temperature. By virtue of a sputtering process executed under the above mentioned conditions, an ITO conductive layer of 30 nm thickness was formed on the microstructure. Hence, a conductive laminate was formed.

The surface roughness of the conductive laminate made by the method of Example 1 was measured using the probing surface roughness meter (available from KOSAKA Laboratory Ltd., Model No. ET4000A). The Ra value was 0.21 μm, Rz value was 0.73 μm, and the Sm value was 0.099 mm. The Ra value refers to a centerline average roughness according to JIS B0601.

### Sliding Test for the Conductive Laminate

A conductive glass having an ITO conductive layer, and the conductive laminate having the ITO conductive layer were prepared. The conductive glass was attached to one side of the conductive laminate through a plurality of spacers, such that the two ITO conductive layers face each other. Another side of the conductive laminate which is opposite to the ITO conductive layer was subjected to the sliding test. The sliding test was carried out under a load of 250 grams using a stylus pen (tip: R0.8) made from formaldehyde resin. The stylus pen was slid and reciprocated 100000 times for a length of 2 cm. This sliding test was practiced using the touch panel friction tester (available from Newsunup Technology Co., Ltd., trade name: SDT-009).

### Surface Resistance Measurement for the Conductive Laminate

Both before and after the sliding test, the electrical resistance of the ITO conductive layer of the conductive laminate was measured by a four-point probe method according to JIS-K7194 using a surface resistance measuring device (available from Mitsubishi Chemical Corporation, trade name: Lotest AMCP-T400). In the following, Ro indicates the electrical resistance of the ITO conductive layer of the conductive laminate before the sliding test, while R indicates the one after the sliding test. In this case, when a ratio of Ro to R is closer to 1, it means the conductive laminate has relatively good structural stability, and the ITO conductive layer is less likely to delaminate from the substrate. The ratio of Ro to R (R/Ro) is listed in the following Table 1.

### Examples 2˜4

In Examples 2˜4, the conductive laminates were prepared and evaluated based on the procedure employed in Example 1 except that, the exposure dose of the first UV light source (the first light source L1) in Example 2˜4 are different and are listed in Table 1. Besides, the surface roughness and the R/Ro values are also listed in Table 1.

TABLE 1

| | | line spacing | | | | |
|---|---|---|---|---|---|---|
| | 1^{st} | (μm) and | | | | |
| | exposure | line width | | | | |
| | dose * | (μm) of the | Ra | Rz | Sm | |
| | (mJ/cm²) | patterned mask | (μm) | (μm) | (mm) | R/Ro |
| Ex. 1 | 520 | 50 | 0.21 | 0.73 | 0.099 | 1.12 |
| | | 50 | | | | |
| Ex. 2 | 1040 | 50 | 0.79 | 2.82 | 0.1 | 1.28 |
| | | 50 | | | | |
| Ex. 3 | 390 | 50 | 0.15 | 0.52 | 0.1 | 1.46 |
| | | 50 | | | | |
| Ex. 4 | 1300 | 50 | 0.92 | 3.21 | 0.1 | 1.58 |
| | | 50 | | | | |

* “The 1^{st} exposure dose” means the exposure dose of the first light source.

According to the results of Examples 1˜4 shown in Table 1, when the Rz value is less than 0.73 μm, or when it is greater than 2.82 μm, the R/Ro value is relatively large, that is, the structural stability of the conductive laminate is relatively poor. Thus, the Rz value preferably ranges from 0.73 μm to 2.82 μm. In general, a conductive laminate for a touch panel is required to have the R/Ro value not greater than 1.3. However, the preferable range of the R/Ro value may be varied based on applications of the conductive laminate.

### Examples 5˜7 and Comparative Example 1 (CE1)

In Examples 5˜7, the conductive laminates were prepared and evaluated following the procedure employed in Example 1 except that, the exposure dose of the first UV light source (the first light source L1) and the line spacings and the line widths of the patterned masks in Example 5˜7 are different and are listed in the following Table 2.

In Comparative Example 1, the conductive laminate was prepared and evaluated following the procedure employed in Example 1 except that, the conductive laminate of Comparative Example 1 did not include the photocurable layer (i.e., the microstructure). That is to say, an ITO conductive layer of 30 nm was directly formed on a polyester-based substrate.

The measured surface roughness and the R/Ro values for Examples 5˜7 and Comparative Example 1 are listed in Table 2. Besides, in Table 2, the parameters for forming the conductive laminate of Example 2 and the results of Example 2 are also listed for comparison.

TABLE 2

| | | line spacing | | | | |
|---|---|---|---|---|---|---|
| | 1^{st} | (μm) and | | | | |
| | exposure | line width | | | | |
| | dose * | (μm) of the | Ra | Rz | Sm | |
| | (mJ/cm²) | patterned mask | (μm) | (μm) | (mm) | R/Ro |
| Ex. 2 | 1040 | 50 | 0.79 | 2.82 | 0.1 | 1.28 |
| | | 50 | | | | |
| Ex. 5 | 1400 | 220 | 0.75 | 2.74 | 0.220 | 1.18 |
| | | 220 | | | | |
| Ex. 6 | 3500 | 340 | 0.68 | 2.78 | 0.349 | 1.42 |
| | | 340 | | | | |
| Ex. 7 | 780 | 25 | 0.72 | 2.75 | 0.05 | 2.05 |
| | | 25 | | | | |
| CE. 1 | — | — | 0.009 | 0.14 | — | 2.85 |

In Table 2, the Rz value is controlled in the preferable range (0.73 μm to 2.82 μm). According to the results shown in Table 2, when the Sm value is less than 0.1 mm or when it is greater than 0.22 mm, the R/Ro value will be increased. Accordingly, a preferable range of Sm value is from 0.1 to 0.22 mm.

In addition, compared to the conductive laminate of Comparative Example 1 without the microstructure, the R/Ro values of the conductive laminates with microstructure (Example 1˜7) are closer to 1. Therefore, it has been demonstrated that, the conductive laminate obtained according to the method of this invention has a better bonding strength between the substrate 21 and the transparent conductive layer 23. This is because the transparent conductive layer 23 has the protruded and indented regions, and is bonded to the microstructure 22 in a relatively large contacting area.

Furthermore, since the upper surface 230 of the transparent conductive layer 23 has the protruded and indented regions, the contact area between the conductive laminate and the conductive glass can be reduced, and damage and delamination of the transparent conductive layer 23 due to repeated pressing operations can be prevented.

While the present invention has been described in connection with what are considered the most practical and preferred embodiments, it is understood that this invention is not limited to the disclosed embodiments but is intended to cover various arrangements included within the spirit and scope of the broadest interpretations and equivalent arrangements.

What is claimed is:

1. A method for making a conductive laminate, comprising:
(a) forming a photocurable layer on a substrate, the photocurable layer including a photocurable composition having at least one photocurable prepolymer that has a plurality of reactive functional groups and that has a functional group equivalent weight ranging from 70 to 700 g/mol;
(b) covering partially the photocurable layer using a patterned mask;
(c) exposing the photocurable layer using a first light source so that the photocurable layer is cured at first regions which are exposed through the patterned mask;
(d) removing the patterned mask;
(e) exposing the photocurable layer using a second light source to cure second regions of the photocurable layer which have not been cured, such that the first and second regions having different surface heights, thereby forming a microstructure on the substrate; and
(f) forming a conductive layer on the microstructure.

2. The method of claim 1, wherein the reactive functional groups include an alkenyl group.

3. The method of claim 1, wherein each of the first regions of the photo curable layer has a width ranging from 50 μm to 250 μm.

4. The method of claim 1, wherein the first light source is UV light, visible light, electron beam, or X-ray.

5. The method of claim 1, wherein the second light source is UV light, visible light, electron beam, or X-ray.

6. The method of claim 1, wherein the first light source is UV light and has an exposure dose of not less than 70 mJ/cm² and not more than 4000 mJ/cm².

7. The method of claim 1, wherein the substrate is made of a polymer selected from the group consisting of polyester-based resin, polyether-based resin, polycarbonate-based resin, polyamide-based resin, polyimide-based resin, polyolefin-based resin, acrylic-based resin, polyvinyl chloride-based resin, polystyrene-based resin, polyvinyl alcohol-based resin, polyarylate-based resin, polyphenylene sulfide-based resin, polyvinylidene chloride-based resin, methacrylate-based resin, acetyl cellulose-based resin, diacetyl cellulose-based resin, triacetyl cellulose-based resin, and combinations thereof.

8. The method of claim 1, wherein:
the conductive layer is made of metal or metallic compound;
the metal is selected from the group consisting of gold, silver, platinum, lead, copper, aluminum, nickel, chromium, titanium, iron, cobalt, tin, and combinations thereof; and
the metallic compound is selected from the group consisting of indium oxide, tin oxide, titanium oxide, aluminum oxide, zinc oxide, gallium oxide, indium tin oxide, and combinations thereof.

9. The method of claim 1, wherein, in the step (f), the conductive layer is formed on the microstructure by a dry process.

10. A conductive laminate made by the method according to claim 1, wherein the microstructure has a Rz value ranging from 0.5 μm to 3.5 μm, and a Sm value ranging from 0.05 mm to 0.35 mm.
